(19) United States
(12) Patent Application Publication
(10) Pub. No.: US 2013/0001630 A1
(43) Pub. Date: Jan. 3, 2013

(54) LIGHT-EMITTING DIODE STRUCTURE

(75) Inventors: Hsin-Ming LO, Pingtung County (TW); Shih-Chang SHEI, Tainan City (TW)

(73) Assignee: ACEPLUX OPTOTECH INC., Tainan City (TW)

(21) Appl. No.: 13/348,792

(22) Filed: Jan. 12, 2012

(30) Foreign Application Priority Data
Jun. 30, 2011 (TW) 100123147

(51) Int. Cl. H01L 33/42

(52) U.S. Cl. 257/99; 257/E33.064

(57) ABSTRACT

A light-emitting diode structure includes first and second conductors, and a light-emitting diode unit. The light-emitting diode unit includes: a light-emitting diode die including first and second polarity sides, and a surrounding surface, the first polarity side being electrically connected to the first conductor; an insulator disposed around the surrounding surface; and a transparent conductive film extending from the second polarity side, along an outer surface of the insulator, and to the second conductor, so that the second polarity side is electrically connected to the second conductor through the transparent conductive film.

### CROSS-REFERENCE TO RELATED APPLICATION

This application claims priority of Taiwanese Patent application no. 100123147, filed on Jun. 30, 2011.

### BACKGROUND OF THE INVENTION

1. Field of the Invention

The present invention relates to a light-emitting diode structure, more particularly to a light-emitting diode structure having a relatively large light emitting area.

2. Description of the Related Art

Light-emitting diodes have been widely used for illumination and in display backlight modules due to their small size, structural stability, short response time, and luminescence property. Light-emitting diodes have attracted much attention in recent years due to their superior energy saving and low pollution characteristics.

Referring to FIG. 1, a conventional light-emitting diode structure comprises a substrate 1, a light-emitting diode die 2 adhered to the substrate 1, and two gold wires 3 that are respectively and electrically connected to the substrate 1 and the light-emitting diode die 2.

The substrate 1 includes two conductors 11 that are spaced apart from each other and that are adapted to connect to an external circuit (not shown).

The light-emitting diode die 2 is adhered to one of the conductors 11 and includes an epitaxial substrate 21, a light emitting unit 22, and two electrodes 23. In consideration of the epitaxial quality of a commonly used gallium nitride-based semiconductor, the epitaxial substrate 21 is preferably made of sapphire. The light emitting unit 22 is formed on the epitaxial substrate 21, and has an n-cladding layer 221, a light emitting layer 222 that is formed on the n-cladding layer 221, and a p-cladding layer 223 that is formed on the light emitting layer 222. The two electrodes 23 are disposed respectively on and are electrically connected to the n-cladding layer 221 and the p-cladding layer 223.

It is noted that the light-emitting diode die 2 is normally provided with a current spreading layer (not shown) that is formed on the p-cladding layer 223 and is mainly made of a metal oxide so as to achieve a more uniform current distribution in the light emitting unit 22. Since the current spreading layer is well known to one of ordinary skill in the art, a description thereof is omitted herein.

The two gold wires 3 are electrically connected to the electrodes 23 and the conductors 11 by means of wire bonding. By virtue of the electrical path formed by the conductors 11, the gold wires 3, and the two electrodes 23 of the light-emitting diode die 2, electricity may be supplied from the external circuit to the light emitting unit 22 of the light-emitting diode die 2, and be converted into light.

The conventional light-emitting diode structure has two major problems. First, since the two electrodes 23 of the light-emitting diode die 2 are made of an opaque metal or metal alloy for providing good electrical conductivity, a part of light emitting outwardly from the light emitting layer 222 may be blocked by the opaque electrodes 23. In addition, the gold wires 3 might also block the light. Second, the arrangement of the electrodes 23 prevents the current in the light emitting unit 22 of the light-emitting diode die 2 from being transferred along a good vertical electrical path, thereby resulting in a poor light emitting efficiency.

### SUMMARY OF THE INVENTION

Therefore, the object of the present invention is to provide a light-emitting diode structure that has improved light emitting efficiency.

Accordingly, a light-emitting diode structure of the present invention comprises: a substrate including first and second conductors that are spaced apart from each other and that are adapted for connection to an external circuit; and a light-emitting diode unit. The light-emitting diode unit includes: a light-emitting diode die disposed on the substrate and including first and second polarity sides that have opposite polarities, and a surrounding surface that is formed between the first and second polarity sides, the first polarity side being electrically connected to the first conductor; an insulator disposed around the surrounding surface of the light-emitting diode die; and a transparent conductive film extending from the second polarity side of the light-emitting diode die oppositely of the substrate, along an outer surface of the insulator, and to the second conductor, so that the second polarity side of the light-emitting diode die is electrically connected to the second conductor through the transparent conductive film, the surrounding surface of the light-emitting diode die being spaced apart from the transparent conductive film by the insulator.

### BRIEF DESCRIPTION OF THE DRAWINGS

Other features and advantages of the present invention will become apparent in the following detailed description of the preferred embodiment with reference to the accompanying drawings, of which:

FIG. 1 is a fragmentary partly cross sectional diagram of a conventional light-emitting diode structure; and

FIG. 2 is a fragmentary partly cross sectional diagram of the preferred embodiment of a light-emitting diode structure according to the present invention.

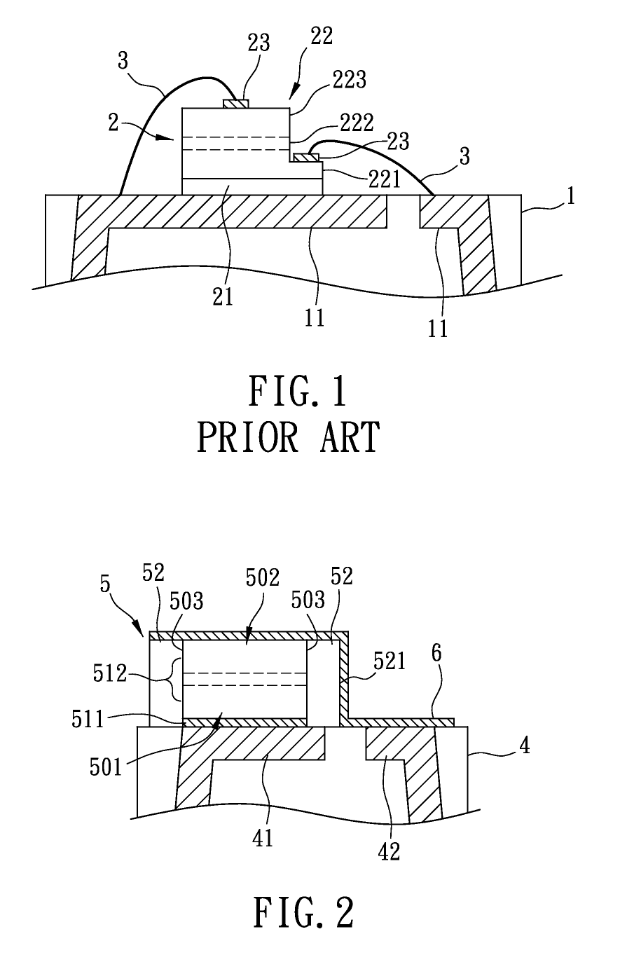

### DETAILED DESCRIPTION OF THE PREFERRED EMBODIMENT

Referring to FIG. 2, the preferred embodiment of a light-emitting diode structure of the present invention comprises a substrate 4 and a light-emitting diode unit 5.

The substrate 4 includes first and second conductors 41, 42 that are spaced apart from each other and that are adapted for connection to an external circuit (not shown).

The light-emitting diode unit 5 includes a light-emitting diode die 512, an insulator 52, and a transparent conductive film 6.

The light-emitting diode die 512 is disposed on the substrate 4 and includes first and second polarity sides 501, 502 that have opposite polarities, and a surrounding surface 503 that is formed between the first and second polarity sides 501, 502. The first polarity side 501 is electrically connected to the first conductor 41. The insulator 52 is disposed around and contacts the surrounding surface 503 of the light-emitting diode die 512. The transparent conductive film 6 contacts and extends from the second polarity side 502 of the light-emitting diode die 512 oppositely of the substrate 4, along an outer surface 521 of the insulator 52, and to the second conductor 42, so that the second polarity side 502 of the light-emitting diode die 512 is electrically connected to the second conductor 42 through the transparent conductive film 6. The surrounding surface 503 of the light-emitting diode die 512 is spaced apart from the transparent conductive film 6 by the insulator 52.

The light-emitting diode unit 5 further includes an electrode layer 511 that is disposed between the light-emitting diode die 512 and the substrate 4, and that is surrounded by the insulator 52. The first polarity side 501 of the light-emitting diode die 512 is electrically connected to the first conductor 41 through the electrode layer 511. The electrode layer 511 and the surrounding surface 503 of the light-emitting diode die 512 are spaced apart from the transparent conductive layer 6 by virtue of the insulator 52.

The electrode layer 511 is made of a material that is electrically conductive and that is capable of reflecting light. Examples of the suitable material include Ni, Ag, Au, Al, Pt, Pd, or alloys thereof. The electrode layer 511 is in ohmic contact with the light-emitting diode die 512 and serves as a substrate for supporting the light-emitting diode die 512 and an electrode for connection with an external circuit.

The light-emitting diode die 512 has a light emitting layer formed between the first polarity side 501 and the second polarity side 502, so that the light-emitting diode die 512 can emit light when electricity is supplied thereto by virtue of photoelectrical effect.

The insulator 52 is made of a transparent material such as silicon oxide, silicon oxynitride, and magnesium fluoride so as to avoid the light emitting from the surrounding surface 503 of the light-emitting diode die 512 from being blocked while providing excellent insulating effect.

More specifically, the light-emitting diode unit 5 has a structure in which current is vertically conducted. The manufacturing process of the light-emitting diode unit 5 includes: epitaxially forming on a sapphire substrate a light-emitting diode die 512 that is made of a gallium nitride-based semiconductor material, followed by forming the electrode layer 511 on the light-emitting diode die 512. Next, the transparent insulator 52 is formed around the surrounding surface 503 of the light-emitting diode die 512 and the electrode layer 511. Finally, the sapphire substrate is removed.

The electrode layer 511 of light-emitting diode unit 5 is then electrically connected and adhered to the first conductor 41 of the substrate 4 by means of a flip chip method.

The transparent conductive film 6 may be formed by means of a vapor deposition or a sputtering technique so as to contact and extend from the second polarity side 502 of the light-emitting diode die 512 oppositely of the substrate 4, along the outer surface 521 of the insulator 52, and to the second conductor 42, so that the second polarity side 502 of the light-emitting diode die 512 is electrically connected to the second conductor 42 through the transparent conductive film 6. In addition, the transparent conductive layer 6 is made of a commonly used transparent conductive metal oxide, such as indium tin oxide, indium oxide, tin oxide, nickel oxide, zinc oxide, or magnesium oxide. The transparent conductive metal oxide allows light transmission and current to be distributed more uniformly, thereby improving the light emitting effect.

To meet the requirements of low resistance and good current path, the transparent conductive layer 6 preferably has a thickness not less than 200 nm (measured from the top of the light-emitting diode die 512). If the thickness of the transparent conductive film 6 is too small, the resistance might be too large and the current distribution might be adversely affected, thereby resulting in poor light emitting uniformity.

More preferably, the transparent conductive layer 6 has a thickness not less than 300 nm.

In the current path from the first conductor 41, through the electrode layer 511, the light-emitting diode die 512, the transparent conductive film 6, and to the second conductor 42, electricity can be applied to the light-emitting diode die 512 of the light-emitting diode unit 5 and can be converted to light by virtue of photoelectrical effect. No short circuit will occur due to the isolation provided by the insulator 52. It is noted that because the light-emitting diode unit 5 has a structure in which the current is vertically conducted, the operation resistance may be reduced and the light emitting efficiency may be enhanced.

In the preferred embodiment, the insulator 52 disposed around the surrounding surface 503 of the light-emitting diode die 512 and the transparent conductive film 6 positioned on top of the light-emitting diode die 512 are both made of a transparent material. Therefore, when electrical power is supplied, the light that emits from the surrounding surface 503 and from the top of the light-emitting diode die 512 will not be blocked. Besides, the electrode layer 511 located at the bottom of the light-emitting diode die 512 is made of a material that is capable of reflecting light. Therefore, light from the light-emitting diode die 512 towards the bottom of the light-emitting diode die 512 can be reflected outwardly by the electrode layer 511, thereby dramatically enhancing the light brightness of the light-emitting diode structure of the present invention.

To sum up, since the light-emitting diode structure of the present invention establishes an electrical connection by means of the transparent conductive film 6 without forming electrodes, light emitting from the light-emitting diode die 512 of the light-emitting diode unit 5 will not be blocked. In addition, a reflection effect can be achieved by means of the electrode layer 511 of the light-emitting diode unit 5. Therefore, not only can the light-blocking area on the light-emitting diode unit 5 be reduced, but the overall light emitting intensity can be enhanced as well.

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

What is claimed is:

1. A light-emitting diode structure, comprising:
a substrate including first and second conductors that are spaced apart from each other and that are adapted for connection to an external circuit; and
a light-emitting diode unit including:
a light-emitting diode die disposed on said substrate and including first and second polarity sides that have opposite polarities, and a surrounding surface that is formed between said first and second polarity sides, said first polarity side being electrically connected to said first conductor;
an insulator disposed around said surrounding surface of said light-emitting diode die; and
a transparent conductive film extending from said second polarity side of said light-emitting diode die oppositely of said substrate, along an outer surface of said insulator, and to said second conductor, so that said second polarity side of said light-emitting diode die is electrically connected to said second conductor through said transparent conductive film, said surrounding surface of said light-emitting diode die being spaced apart from said transparent conductive film by said insulator.

2. The light-emitting diode structure of claim 1, wherein said light-emitting diode unit further includes an electrode layer that is disposed between said light-emitting diode die and said substrate, and that is surrounded by said insulator, said first polarity side of said light-emitting diode die being electrically connected to said first conductor through said electrode layer.

3. The light-emitting diode structure of claim 2, wherein said electrode layer is made of a material that is electrically conductive and that is capable of reflecting light.

4. The light-emitting diode structure of claim 1, wherein said insulator is made of a material selected from the group consisting of silicon oxide, silicon oxynitride, and magnesium fluoride.

5. The light-emitting diode structure of claim 1, wherein said transparent conductive layer is made of a material selected from the group consisting of indium tin oxide, indium oxide, tin oxide, nickel oxide, zinc oxide, and magnesium oxide.

6. The light-emitting diode structure of claim 1, wherein said transparent conductive layer has a thickness not less than 200 nm.

7. The light-emitting diode structure of claim 1, wherein said transparent conductive layer has a thickness not less than 300 nm.

8. A light-emitting diode unit for mounting on a substrate, comprising:
a light-emitting diode die including first and second polarity sides that have opposite polarities, and a surrounding surface that is formed between said first and second polarity sides, said first polarity side being adapted to be mounted to the substrate;
an insulator disposed around said surrounding surface of said light-emitting diode die; and
a transparent conductive film extending from said second polarity side to an outer surface of said insulator, and having a thickness of not less than 300 nm.

9. The light-emitting diode unit of claim 8, further comprising an electrode layer that is disposed under said light-emitting diode die, and that is surrounded by said insulator, said first polarity side being adapted to be mounted to the substrate through said electrode layer.

10. The light-emitting diode unit of claim 8, wherein said insulator is made of a material selected from the group consisting of silicon oxide, silicon oxynitride, and magnesium fluoride.

11. The light-emitting diode unit of claim 9, wherein said electrode layer is made of a material that is electrically conductive and that is capable of reflecting light.
